(19) United States
(12) Patent Application Publication
(10) Pub. No.: US 2020/0131629 A1
(43) Pub. Date: Apr. 30, 2020

(54) CLEANING METHOD OF A THIN FILM DEPOSITION CHAMBER AND METHOD OF MANUFACTURING SEMICONDUCTOR DEVICE USING THE CLEANING METHOD

(71) Applicant: Samsung Electronics Co., Ltd., Suwon-si (KR)

(72) Inventors: Myung-Joon PARK, Seoul (KR); Jin-Gwan KIM, Suwon-si (KR); Min-Hye PARK, Yongin-si (KR); Joo-Myoung PARK, Yongin-si (KR); Sang-Hwan AN, Suwon-si (KR)

(21) Appl. No.: 16/448,471

(22) Filed: Jun. 21, 2019

(30) Foreign Application Priority Data
Oct. 29, 2018 (KR) 10-2018-0129915

(51) Int. Cl. C23C 16/44; H01J 37/32; B08B 7/00

(52) U.S. Cl. CPC C23C 16/4405; B08B 7/0035; H01J 37/32862

(57) ABSTRACT

A cleaning method of a thin film deposition chamber may include i) simultaneously providing oxygen plasma and fluorine plasma in a thin film deposition chamber to at least partially remove a first residue including carbon (C) and a second residue including silicon (Si) in the thin film deposition chamber, and ii) providing fluorine plasma without oxygen plasma in the thin film deposition chamber to remove the second residue remaining in the thin film deposition chamber.

### CROSS-REFERENCE TO RELATED APPLICATION

This application claims priority under 35 USC § 119 to Korean Patent Application No. 10-2018-0129915, filed on Oct. 29, 2018 in the Korean Intellectual Property Office (KIPO), the contents of which are herein incorporated by reference in their entirety.

### BACKGROUND

### 1. Field

Example embodiments relate to a cleaning method of a thin film deposition chamber and a method of manufacturing a semiconductor device using the cleaning method. More particularly, example embodiments relate to a cleaning method of a thin film deposition chamber with a residue therein.

### 2. Description of the Related Art

A thin film deposition process may be performed in a manufacturing process of a semiconductor device, a display device, etc. The thin film deposition process may be performed using a thin film deposition chamber, however, a residue including carbon (C) and/or silicon (Si) as a reaction by-product may be formed. When the residue remains in the thin film deposition chamber without being completely removed, a thin film may not be uniformly formed in a subsequent thin film deposition process, and thus the quality of a final product including the thin film may be deteriorated.

### SUMMARY

Example embodiments provide an efficient cleaning method of a thin film deposition chamber.

According to example embodiments, there is provided a cleaning method of a thin film deposition chamber. The cleaning method may include i) simultaneously providing oxygen plasma and fluorine plasma in a thin film deposition chamber to at least partially remove a first residue including carbon (C) and a second residue including silicon (Si) in the thin film deposition chamber, and ii) providing fluorine plasma without oxygen plasma in the thin film deposition chamber to remove the second residue remaining in the thin film deposition chamber.

According to example embodiments, there is provided a cleaning method of a thin film deposition chamber. The cleaning method may include i) supplying oxygen (O₂) gas into a thin film deposition chamber to partially remove a first residue including carbon (C) in the thin film deposition chamber, ii) simultaneously providing oxygen plasma and fluorine plasma in the thin film deposition chamber to at least partially remove the first residue and a second residue including silicon (Si) in the thin film deposition chamber, and iii) providing fluorine plasma without oxygen plasma in the thin film deposition chamber to remove the second residue remaining in the thin film deposition chamber.

According to example embodiments, there is provided a cleaning method of a thin film deposition chamber. The cleaning method may include i) providing oxygen (O₂) plasma without fluorine plasma in a thin film deposition chamber to partially remove a first residue including carbon (C) in the thin film deposition chamber, ii) simultaneously providing oxygen plasma and fluorine plasma in the thin film deposition chamber to at least partially remove the first residue and a second residue including silicon (Si) in the thin film deposition chamber, iii) providing fluorine plasma without oxygen plasma in the thin film deposition chamber to remove the second residue remaining in the thin film deposition chamber, and iv) supplying an inert gas into the thin film deposition chamber to separate remaining first residue and/or the remaining second residue from the thin film deposition chamber.

According to an embodiment, a method of manufacturing a semiconductor device includes i) forming a first residue including carbon (C) and a second residue including silicon (Si) in a thin film deposition chamber while depositing a thin film on a substrate; ii) simultaneously providing oxygen plasma and fluorine plasma in the thin film deposition chamber to at least partially remove the first residue and the second residue in the thin film deposition chamber; iii) providing fluorine plasma without oxygen plasma in the thin film deposition chamber to remove the second residue remaining in the thin film deposition chamber; iv) placing a substrate in the thin film deposition chamber; and v) forming a film on the substrate.

A cleaning method of a thin film deposition chamber in accordance with example embodiments may effectively remove a residue including carbon (C) and/or silicon (Si) by using an oxygen plasma and a fluorine plasma. Accordingly, a thin film may be uniformly formed in a subsequent thin film deposition process, and thus the quality of a final product including the thin film may be improved.

### BRIEF DESCRIPTION OF THE DRAWINGS

FIG. 1 is a cross-sectional view illustrating a thin film deposition apparatus in accordance with example embodiments.

FIGS. 2 to 4 are flow charts illustrating a cleaning method of a thin film deposition chamber in accordance with example embodiments.

### DESCRIPTION OF EMBODIMENTS

A cleaning method of a thin film deposition chamber in accordance with example embodiments will be described more fully hereinafter with reference to the accompanying drawings.

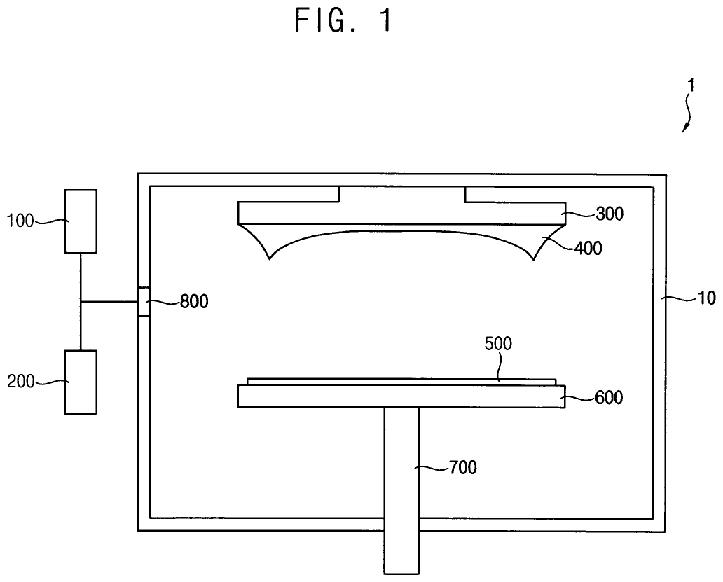

FIG. 1 is a cross-sectional view illustrating a thin film deposition apparatus in accordance with example embodiments.

Referring to FIG. 1, a thin film deposition apparatus 1 may include a thin film deposition chamber 10, a gas supply unit 100 and a plasma generating unit 200.

The thin film deposition chamber 10 may include a shower head 300 spraying gases for forming a thin film, a support unit 600 supporting a substrate 500 on which the thin film may be formed, a driving unit 700 for moving the support unit 600 upwardly/downwardly and/or fastening the support unit 600, and a penetration unit 800 connected to the outside.

Thin film deposition processes may be performed in the thin film deposition chamber 10, and various by-products may be formed in the chamber 10. Various processing gases may be provided during thin film deposition processes. The processing gases may be discharged after performing the thin film deposition processes. When the processing gases are discharged, some of the by-products may be discharged together with the processing gasses, and some other by-products may remain in the chamber 10, e.g., in a form of a residue. After performing a thin film deposition process, e.g., a chemical vapor deposition (CVD) process, the remainder of reaction by-products generated/remaining in the thin film deposition process, i.e., a residue 400 may remain on a surface of the shower head 300 of the thin film deposition chamber 10.

In order to remove the residue 400 remaining in the thin film deposition chamber 10 after performing the thin film deposition process, the gas supply unit 100 may supply an oxygen source gas and/or a fluorine source gas to the plasma generating unit 200 which may activate the oxygen source gas and/or the fluorine source gas supplied from the gas supply unit 100 to form oxygen plasma and/or fluorine plasma, respectively.

Each of the oxygen plasma and/or the fluorine plasma may be supplied into the thin film deposition chamber 10 through the penetration unit 800, and may be used to remove the residue 400 on the surface of the shower head 300. For example, the penetration unit 800 may be a pipe configured to supply the oxygen plasma and the fluorine plasma. In certain embodiments, the oxygen source gas and/or the fluorine source gas may be supplied into the thin film deposition chamber 10 through the penetration unit 800. For example, processing gases forming a thin film in the thin film deposition chamber 10 may be supplied through the shower head 300, and cleaning gas/plasma may be supplied through the penetration unit 800. In this way, the processing gas and the cleaning gas may be protected from a contamination from each other. However, in certain other embodiments, the cleaning gas/plasma may be supplied through the shower head 300. In this case, the cleaning gas supply and the processing gas supply may be controlled by respective valves connected to respective gas reservoirs.

In example embodiments, the oxygen source gas may include oxygen (O₂), and the fluorine source gas may include at least one selected from the group consisting of NF₃, CF₄ and C₂F₆. In certain embodiments the oxygen source gas may be oxygen gas.

In example embodiments, the residue 400 may include SiCN, SiCOH, Ultra low K (ULK) SiCOH, etc., depending on material involved in the thin film deposition process. For example, when a SiCN film is deposited, the generated residue may also include SiCN, and when a SiCOH film or a ULK SiCOH film is deposited, the generated residue may also include SiCOH.

In example embodiments, the substrate 500 may be a substrate used for manufacturing a semiconductor device, and may include semiconductor materials, e.g., silicon, germanium, silicon-germanium, etc., or compounds e.g., gallium phosphide (GaP), gallium arsenide (GaAs), gallium antimonide (GaSb), etc. in one embodiment, the substrate 500 may be a silicon-on-insulator (SOI) substrate or a germanium-on-insulator (GOI) substrate.

Alternatively, the substrate 500 may be a substrate used for manufacturing a display device, and may include an insulating material, e.g., glass, quartz, or plastic. The plastic may include polyethylene terephthalate, polyethylene naphthalate, polyether ketone, polycarbonate, polyacrylate, polyether sulfone, polyimide, etc.

Hereinafter, a cleaning method of the thin film deposition chamber 10 so as to remove the residue remaining in the thin film deposition chamber 10 of the thin film deposition apparatus 1 will be described.

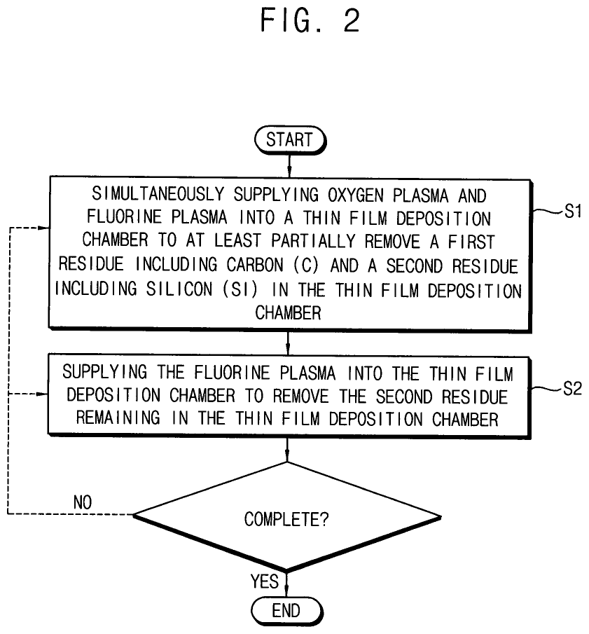

FIG. 2 is a flow chart illustrating a cleaning method of a thin film deposition chamber in accordance with example embodiments.

Referring to FIGS. 1 and 2, the cleaning method of the thin film deposition chamber 10 may include simultaneously supplying oxygen plasma and fluorine plasma into the thin film deposition chamber 10 to at least partially remove a first residue including carbon (C) and a second residue including silicon (Si) in the thin film deposition chamber 10 (step S1), and then supplying the fluorine plasma to the thin film deposition chamber 10 to remove the second residue remaining in the thin film deposition chamber 10 (step S2). In one embodiments, the cleaning method may be performed under an internal pressure of the film deposition chamber 10 within a range of about 1 to 10 about Torr at an internal temperature of the thin film deposition chamber 10 within a range of about 200 to about 400° C. In certain embodiments, the oxygen plasma and the fluorine plasma may be provided in the thin film deposition chamber 10 by supplying corresponding source gases into the thin film deposition chamber 10 and then generating plasma thereof at step S1. In certain embodiments, the fluorine plasma may be provided in the thin film deposition chamber 10 by supplying a corresponding source gas into the thin film deposition chamber 10 and then generating plasma thereof at step S2. This may also be applied to other embodiments described below.

Step S1 and step S2 sequentially performed altogether may constitute one cycle, and the cycle may be repeatedly performed until the first and second residues may be sufficiently removed. Alternatively, when the first residue is sufficiently removed, while the second residue remains, after performing one time or plural times of the cycle including step S1 and step S2, only step S2 may be performed once or a plurality of times. For example, while the cycle of step S1 and step S2 is performed/repeated, an electric field and/or microwaves may be generated inside the thin film deposition chamber 10 to maintain the plasma state of the oxygen plasma and the fluorine plasma. In certain embodiments, the oxygen source gas and the fluorine source gas may be supplied into the thin film deposition chamber 10, and an electric field and/or microwaves may be used to form oxygen plasma and fluorine plasma.

In example embodiments, in a cleaning process for removing the residue 400 including SiCN, the cycle including step S1 and step S2 may be performed twice. In certain embodiments, in a cleaning process for removing the residue 400 including SiCOH or ULK SiCOH, the cycle including step S1 and step S2 may be performed three times.

In some embodiments, before performing step S1, an oxygen (O₂) gas treatment may be performed to partially remove the first residue in the thin film deposition chamber 10. For example, the oxygen gas treatment may be a chemical reaction treatment with the first residue and/or plasma treatment by generating a plasma with the oxygen gas in the thin film deposition chamber 10.

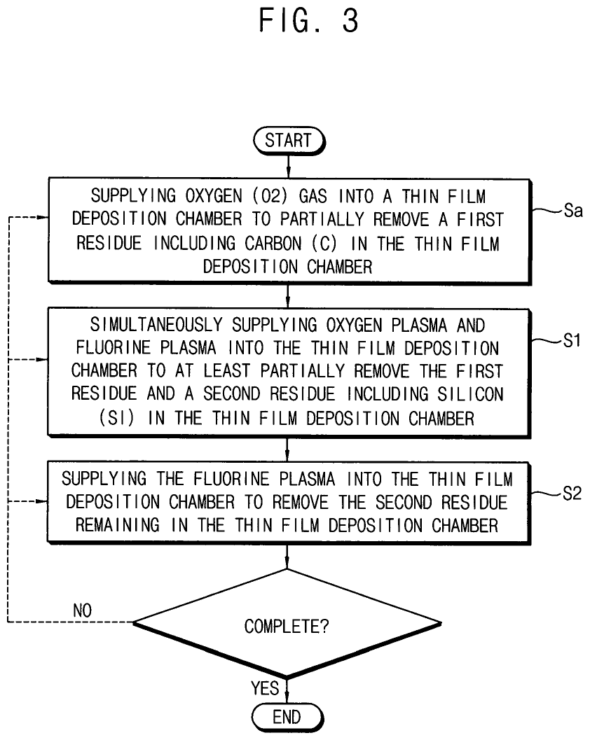

The oxygen gas treatment may be performed once, so that FIG. 2 illustrates that the oxygen gas treatment is not included in the cycle. For example, in the current embodiment, the oxygen gas treatment may be performed before performing the cycle of step S1 and step S2, and the oxygen gas treatment may not be performed while the cycle of step S1 and step S2 is repeated. However, the inventive concept may not be limited thereto, and in certain embodiments, the oxygen gas treatment may be included in the cycle and may also be performed more than once, which will be described later with reference to FIG. 3.

After step S1 and/or step S2, an inert gas may be supplied to the thin film deposition chamber 10 to separate the remaining first residue and/or the remaining second residue from the thin film deposition chamber 10. In certain embodiments, electric field/microwave may be applied to the inert gas to form a plasma with the inert gas and to separate/remove the remaining first/second residues from the thin film deposition chamber 10.

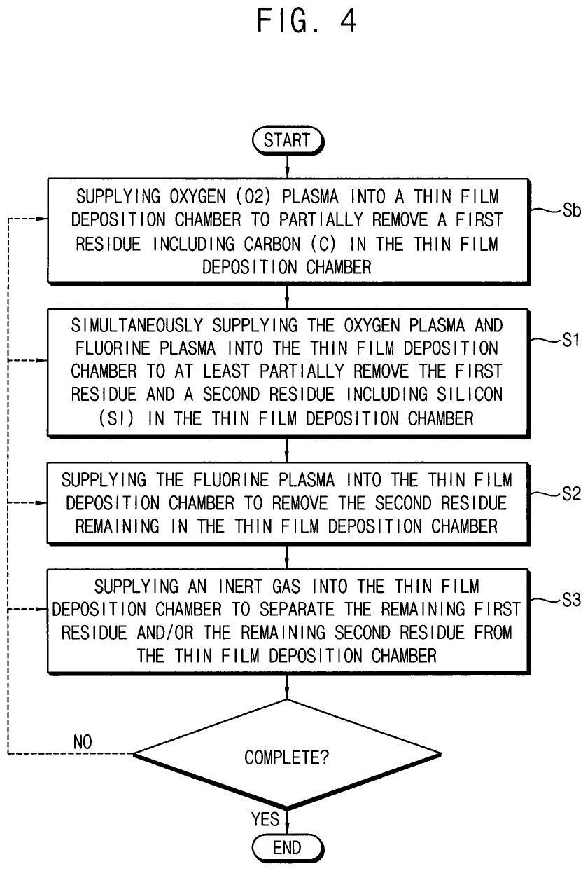

However, the residue separation process using the inert gas may be performed once, so that FIG. 2 illustrates that the residue separation process is not included in the cycle. For example, in the current embodiment, the residue separation process may be performed after performing the cycle of step S1 and step S2, and the residue separation process may not be performed while the cycle of step S1 and step S2 is repeated. However, the inventive concept is not limited thereto, and in certain embodiments, residue separation process may be included in the cycle and may be performed more than once, which will be described later with reference to FIG. 4.

In one embodiment, the inert gas may include at least one selected from the group consisting of helium (He), argon (Ar) and nitrogen (N₂).

The oxygen plasma and the fluorine plasma may be generated by supplying an oxygen source gas and a fluorine source gas altogether from the gas supply unit 100 to the plasma generating unit 200, and the oxygen source gas and the fluorine source may not be reacted with each other in the plasma generating unit 200. For example, the oxygen source gas and the fluorine source gas may be turned into free radicals in the plasma generating unit 200. The free radicals may be formed by hemolysis or hemolytic fission. In certain embodiments, the free radicals may be formed by electron redox. For example, the free radicals may be formed by ultraviolet radiation, heat and/or electric field.

Also, when the oxygen source gas and the fluorine source are activated to generate the oxygen plasma and the fluorine plasma, respectively, in the plasma generating unit 200, the oxygen plasma and the fluorine plasma may not react with each other. Rather, the oxygen plasma and the fluorine plasma may share separated electrons, and the activation of unreacted oxygen source gas and fluorine source gas may be promoted.

The oxygen source gas may include oxygen (O₂), and the fluorine source gas may include at least one selected from the group consisting of NF₃, CF₄ and C₂F₆. In one embodiment, the oxygen source gas and the fluorine source gas may be supplied from the gas supply unit 100 to the plasma generating unit 200 at a flow ratio of the oxygen source gas to the fluorine source gas to be about 1:1.

FIG. 3 is a flow chart illustrating a cleaning method of a thin film deposition chamber in accordance with example embodiments.

This cleaning method of the thin film deposition chamber is substantially the same as or similar to the cleaning method of the thin film deposition chamber described in FIG. 2, except that an oxygen gas treatment is included in the cycle. Accordingly, like reference numerals refer to like elements, and detailed descriptions thereon are omitted herein. The oxygen gas treatment process may be the same as the one described with respect to the embodiment illustrated in FIG. 2.

Referring to FIGS. 1 and 3, the cleaning method of the thin film deposition chamber 10 may include supplying oxygen gas (02) to partially remove a first residue including carbon (C) in the thin film deposition chamber 10 (step Sa), simultaneously supplying oxygen plasma and fluorine plasma to the thin film deposition chamber 10 to at least partially remove the first residue and a second residue including silicon (Si) in the thin film deposition chamber 10 (step S1), and supplying the fluorine plasma to the thin film deposition chamber 10 to remove the second residue remaining in the thin film deposition chamber 10 (step S2).

Step Sa, step S1 and step S2 sequentially performed altogether may constitute one cycle, and the cycle may be repeatedly performed until the first and second residues may be sufficiently removed. Alternatively, for example, when the first residue and the second residue partially remain, after performing/repeating the cycle including step Sa, step S1 and step S2, only step S1 and step S2 may be repeatedly performed. In certain embodiments, when the first residue is sufficiently removed, while the second residue remains, after performing the cycle including step Sa, step S1 and step S2, only step S2 may be repeatedly performed. For example, after repeating the cycle of steps Sa, S1 and S2, selected steps Sa and S1, or selected steps S1 and S2 may be repeated depending on remaining state of residue.

Although not shown, a residue separation process may be further performed after the cycle including step Sa, step S1 and step S2. In this case, step Sa, step S1, step S2 and the residue separation process altogether may constitute the cycle. For example, the residue separation process may be the same process as the one described above. For example, the rescue separation process may use an inert gas and/or a plasma generated by using an inert gas.

FIG. 4 is a flow chart illustrating a cleaning method of a thin film deposition chamber in accordance with example embodiments.

This cleaning method of the thin film deposition chamber is substantially the same as or similar to the cleaning method of the thin film deposition chamber described in FIG. 2, except that an oxygen gas treatment and a residue separation process are included in the cycle. Accordingly, like reference numerals refer to like elements, and detailed descriptions thereon are omitted herein. For example, the oxygen gas treatment process and the residue separation process may be respectively the same processes as the ones described above.

Referring to FIGS. 1 and 4, the cleaning method of the thin film deposition chamber 10 may include supplying oxygen plasma to partially remove a first residue including carbon (C) in the thin film deposition chamber 10 (step Sb), simultaneously supplying the oxygen plasma and fluorine plasma to the thin film deposition chamber 10 to at least partially remove the first residue and a second residue including silicon (Si) in the thin film deposition chamber 10 (step S1), supplying the fluorine plasma to the thin film deposition chamber 10 to remove the second residue remaining in the thin film deposition chamber 10 (step S2), and supplying an inert gas into the thin film deposition chamber 10 to separate the remaining first residue and/or the remaining second residue from the thin film deposition chamber 10 (step S3). In certain embodiments, an electric field or a microwave may be applied to the inert gas to form a plasma with the inert gas. For example, the separation/removal of the first/second residue may be performed by a physical collision of plasma into the residue and/or by a chemical reaction between radicals of the plasma and the residue material.

For example, step Sb may be performed in place of step Sa described in FIG. 3, and may partially remove the first residue by supplying the oxygen plasma alone to the thin film deposition chamber 10. While performing step Sb, the oxygen plasma may partially remove the second residue.

The oxygen plasma may be generated by supplying an oxygen source gas from the gas supply unit 100 to the plasma generating unit 200, and activating the oxygen source gas in the plasma generating unit 200. In one embodiment, the oxygen source gas may include oxygen (O₂). For example, the oxygen source gas may be oxygen gas. In certain embodiments, the oxygen plasma may be generated by supplying an oxygen source gas into the thin film deposition chamber 10 and applying electric field to the oxygen source gas similarly to the previous embodiment. In the embodiment where the oxygen plasma is generated from the plasma generating unit 200 and then supplied into the thin film deposition chamber 10, electric field may be applied to the oxygen plasma while the oxygen plasma stays inside the thin film deposition chamber 10, e.g., during the step Sb, to maintain the plasma state of the oxygen plasma.

In example embodiments, step Sb, step S1, step S2 and step S3 sequentially performed altogether may constitute one cycle, and the cycle may be repeatedly performed until the first and second residues may be sufficiently removed.

Alternatively, for example, when the first residue and the second residue partially remain, after performing the cycle including step Sb and steps S1 to S3, only steps S1 to S3 may be repeatedly performed. In certain embodiments, when the first residue and the second residue partially remain after performing the cycle including step Sb and steps S1 to S3, only steps S2 and S3 may be repeatedly performed. When the first residue is sufficiently removed, while the second residue remains, after performing the cycle including step Sb and steps S1 to S3, only step S3 may be repeatedly performed. For example, after repeating the cycle of steps Sb, S1, S2 and S3, one or more steps of the cycle may be selected and repeated depending on remaining state of residue.

Hereinafter, a method of manufacturing a semiconductor device according to an embodiment of the present disclosure will be described.

According to the method of manufacturing a semiconductor device, a thin film deposition chamber 10 may be cleaned using one of the embodiments described above, And then, a substrate 500 may be provided into the chamber 10 on the support 600, The substrate 500 may be a semiconductor substrate, for example, a crystalline silicon substrate, a crystalline germanium substrate or a crystalline silicon-germanium substrate and be in the form of a wafer. Various semiconductor patterns and various conductor patterns may be formed on the substrate to form circuits including transistors, capacitors and/or switches via a plurality of manufacturing processes including multiple steps of photolithography processes. Within the deposition chamber 10, a thin film may be formed on the semiconductor substrate 500. The semiconductor substrate 500 may be a bare substrate, or one or more layers of patterns and/or thin films may be formed on the substrate 500 before the substrate 500 is supplied into the thin film deposition chamber 10 and has the thin film formed thereon. The thin film formed on the substrate 500 may be patterned to form a circuit and/or insulation patterns as part of an integrated circuit of the semiconductor device being formed. For example, the thin film formed in the thin film deposition chamber 10 may be a conductor film or an insulator film. After forming various circuits on the substrate 500, the resulting wafer including the substrate may be diced and packaged.

As described above, the cleaning method of the thin film deposition chamber may effectively remove the residue including carbon and/or silicon by using the oxygen plasma and the fluorine plasma. Accordingly, the thin film may be uniformly formed in a subsequent thin film deposition process, and thus the quality of a final product including the thin film may be improved. For example, the subsequent thin film deposition process may be controlled for the chamber to be maintained in a proper condition for the process, e.g., without particles, and the quality of the thin film formed by the process may be improved.

1. A cleaning method of a thin film deposition chamber, the cleaning method comprising:
i) simultaneously providing oxygen plasma and fluorine plasma in a thin film deposition chamber to at least partially remove a first residue including carbon (C) and a second residue including silicon (Si) in the thin film deposition chamber; and
ii) providing fluorine plasma without oxygen plasma in the thin film deposition chamber to remove the second residue remaining in the thin film deposition chamber.

2. The cleaning method of claim 1, wherein steps i) and ii) are sequentially and repeatedly performed.

3. The cleaning method of claim 1, wherein after performing steps i) and ii), step ii) is repeatedly performed.

4. The cleaning method of claim 1, wherein the oxygen plasma and the fluorine plasma are generated by simultaneously supplying an oxygen source gas and a fluorine source gas into a plasma generating unit.

5. The cleaning method of claim 4, wherein the oxygen source gas includes oxygen (O₂), and the fluorine source gas includes at least one selected from a group consisting of NF₃, CF₄ and C₂F₆.

6. The cleaning method of claim 1, wherein steps i) and ii) occur without any substrate in the thin film deposition chamber.

7. The cleaning method of claim 1, before performing step i), the cleaning method further comprises:
performing an oxygen (O₂) gas treatment to partially remove the first residue in the thin film deposition chamber.

8. The cleaning method of claim 1, further comprising:
supplying an inert gas into the thin film deposition chamber to separate the first residue and/or the second residue from the thin film deposition chamber.

9. The cleaning method of claim 8, wherein the inert gas includes at least one selected from the group consisting of helium (He), argon (Ar) and nitrogen (N₂).

10. The cleaning method of claim 8, wherein supplying the inert gas into the thin film deposition chamber is performed after performing step ii).

11. The cleaning method of claim 8, wherein supplying the inert gas into the thin film deposition chamber is performed after performing step i).

12. A cleaning method of a thin film deposition chamber, the cleaning method comprising:
i) supplying oxygen (O₂) gas into a thin film deposition chamber to partially remove a first residue including carbon (C) in the thin film deposition chamber;
ii) simultaneously providing oxygen plasma and fluorine plasma in the thin film deposition chamber to at least partially remove the first residue and a second residue including silicon (Si) in the thin film deposition chamber; and
iii) providing fluorine plasma without oxygen plasma in the thin film deposition chamber to remove the second residue remaining in the thin film deposition chamber.

13. The cleaning method of claim 12, wherein steps i) to iii) are sequentially and repeatedly performed.

14. The cleaning method of claim 12, wherein after performing steps i) to iii) one or more times, steps ii) and iii) are sequentially and repeatedly performed.

15. The cleaning method of claim 12, further comprising:
supplying an inert gas into the thin film deposition chamber to separate the first residue and/or the second residue from the thin film deposition chamber.

16. The cleaning method of claim 15, wherein supplying the inert gas into the thin film deposition chamber is performed after performing step iii).

17. A cleaning method of a thin film deposition chamber, the cleaning method comprising:
i) providing oxygen (O₂) plasma without fluorine plasma in a thin film deposition chamber to partially remove a first residue including carbon (C) in the thin film deposition chamber;
ii) simultaneously providing oxygen plasma and fluorine plasma in the thin film deposition chamber to at least partially remove the first residue and a second residue including silicon (Si) in the thin film deposition chamber;
iii) providing fluorine plasma without oxygen plasma in the thin film deposition chamber to remove the second residue remaining in the thin film deposition chamber; and
iv) supplying an inert gas into the thin film deposition chamber to separate remaining first residue and/or the remaining second residue from the thin film deposition chamber.

18. The cleaning method of claim 17, wherein steps i) to iv) are sequentially and repeatedly performed.

19. The cleaning method of claim 17, wherein after performing steps i) to iv), steps ii) to iv) are sequentially and repeatedly performed.

20. The cleaning method of claim 17, wherein after performing steps i) to iv), steps iii) and iv) are sequentially and repeatedly performed.

21-25. (canceled)
